(19) United States
(12) Patent Application Publication
(10) Pub. No.: US 2026/0189819 A1
(43) Pub. Date: Jul. 2, 2026

(54) PIXEL CIRCUIT, ELECTRONIC DEVICE, AND IMAGE OBTAINING METHOD

(71) Applicant: VIVO MOBILE COMMUNICATION CO., LTD., Dongguan (CN)

(72) Inventor: Bing HAN, Dongguan (CN)

(73) Assignee: VIVO MOBILE COMMUNICATION CO., LTD., Dongguan (CN)

(21) Appl. No.: 19/539,645

(22) Filed: Feb. 13, 2026

Related U.S. Application Data
(63) Continuation of application No. PCT/CN2024/113334, filed on Aug. 20, 2024.

(30) Foreign Application Priority Data
Aug. 23, 2023 (CN) 202311064253.0

(51) Int. Cl. H04N 25/772; H04N 25/778; H03M 1/12

(52) U.S. Cl. CPC H04N 25/772; H04N 25/778; H03M 1/12

(57) ABSTRACT

This application provides a pixel circuit, an electronic device, and an image obtaining method. The pixel circuit includes a photosensitive diode array and at least one voltage detection circuit, where m photosensitive diodes in the photosensitive diode array are electrically connected to one voltage detection circuit, the voltage detection circuit is configured to: detect a digital voltage value corresponding to an analog voltage outputted by a first photosensitive diode in the m photosensitive diodes and a ratio of an analog voltage outputted by m–1 second photosensitive diodes in the m photosensitive diodes to the analog voltage outputted by the first photosensitive diode, and determine a digital voltage value of the m–1 second photosensitive diodes based on the digital voltage value of the first photosensitive diode and the ratio.

### CROSS-REFERENCE TO RELATED APPLICATIONS

This application is a continuation application of PCT International Application No. PCT/CN2024/113334 filed on August 20, 2024, which claims priority to Chinese Patent Application No. 202311064253.0, entitled "PIXEL CIRCUIT, ELECTRONIC DEVICE, AND IMAGE OBTAINING METHOD", and filed with the China National Intellectual Property Administration on August 23, 2023, which is incorporated by reference in its entirety.

### TECHNICAL FIELD

This application relates to the field of electronic product technologies, and in particular, to a pixel circuit, an electronic device, and an image obtaining method.

### BACKGROUND

With the development of electronic products, photo and video functions in the electronic products become more perfect, and are widely used. Before each pixel in a camera sensor of an electronic product (for example, a terminal device) is sensitive to light, a charge accumulated in a photosensitive diode needs to be cleared first, and then an optical signal is integrated within a set exposure time, to generate an electron. Next, the electron needs to be converted into a voltage, and then the electron is converted into a digital value through digital-to-analog conversion, to generate an image. Currently, in the electronic product, a pixel circuit is generally disposed for each column of photosensitive diodes (PDs), and the pixel circuit includes an analog to digital converter (ADC) and an integration circuit, so that a digital voltage value corresponding to an analog voltage outputted by the PD is obtained by integrating the optical signal. Because digital voltage values of one row of PDs may be obtained at a time, digital voltage values of all PDs need to be obtained by scanning row by row, and finally a pattern is generated based on the digital voltage values of all the PDs. In this way, a time delay in image generation is large.

### SUMMARY

Embodiments of this application provide a pixel circuit, an electronic device, and an image obtaining method.

According to a first aspect, an embodiment of this application provides a pixel circuit, including a photosensitive diode array and at least one voltage detection circuit, where

m photosensitive diodes in the photosensitive diode array are electrically connected to one voltage detection circuit, and the voltage detection circuit is configured to: detect a digital voltage value corresponding to an analog voltage outputted by a first photosensitive diode in the m photosensitive diodes and a ratio of an analog voltage outputted by m–1 second photosensitive diodes in the m photosensitive diodes to the analog voltage outputted by the first photosensitive diode, and determine a digital voltage value of the m–1 second photosensitive diodes based on the digital voltage value of the first photosensitive diode and the ratio; and

the m photosensitive diodes include at least one row or at least one column of photosensitive diodes in the photosensitive diode array.

According to a second aspect, an embodiment of this application further provides an electronic device, including the pixel circuit according to the first aspect.

According to a third aspect, an embodiment of this application further provides an image obtaining method, applied to the electronic device according to the second aspect, and the method includes:

detecting a digital voltage value corresponding to an analog voltage outputted by a first photosensitive diode in m photosensitive diodes and a ratio of an analog voltage outputted by m–1 second photosensitive diodes in the m photosensitive diodes to the analog voltage outputted by the first photosensitive diode;

determining the digital voltage value of the m–1 second photosensitive diodes based on the digital voltage value of the first photosensitive diode and the ratio; and

generating an image based on the digital voltage value of the first photosensitive diode and the digital voltage value of the m–1 second photosensitive diodes, where

the m photosensitive diodes include at least one row or at least one column of photosensitive diodes in a photosensitive diode array.

### BRIEF DESCRIPTION OF THE DRAWINGS

The foregoing and/or additional aspects and advantages of this application will become apparent and comprehensible from the following descriptions of the embodiments with reference to the accompanying drawings.

FIG. 1 is a first diagram of a structure of a pixel circuit according to an embodiment of this application;

FIG. 2 is a second diagram of a structure of a pixel circuit according to an embodiment of this application;

FIG. 3 is a third diagram of a structure of a pixel circuit according to an embodiment of this application;

FIG. 4 is a diagram of a structure of a mixed analog-to-digital conversion circuit in a pixel circuit according to an embodiment of this application; and

FIG. 5 is a schematic flowchart of an image obtaining method according to an embodiment of this application.

### DETAILED DESCRIPTION

Embodiments of this application are described below in detail, and examples of the embodiments are shown in the accompanying drawings, where the same or similar elements or the elements having same or similar functions are denoted by the same or similar reference numerals throughout the descriptions. Embodiments described below with reference to the accompanying drawings are exemplary and used only for explaining this application, and should not be construed as a limitation on this application.

Features of terms "first" and "second" in the specification and claims of this application may explicitly or implicitly include one or more of the features. In the descriptions of this application, unless otherwise stated, "a plurality of" refers to two or more. In addition, "and/or" in the specification and the claims represents at least one of connected objects, and the character "/" generally represents an "or" relationship between associated objects.

In the descriptions of this application, it should be understood that, orientations or position relationships indicated by terms such as "central", "longitudinal", "transverse", "length", "width", "thickness", "above", "below", "front", "rear", "left", "right", "vertical", "horizontal", "top", "bottom", "inside", "outside", "clockwise", "counterclockwise", "axial", " radial", and "circumferential" are orientations or position relationships indicated based on the accompanying drawings, and are merely used for describing this application and simplifying the descriptions, rather than indicating or implying that the mentioned apparatus or element needs to have a particular orientation or needs to be constructed and operated in a particular orientation. Therefore, such terms should not be construed as a limiting to this application.

In the descriptions of this application, it should be noted that, unless otherwise clearly specified and defined, terms such as "mounting", "interconnection", and "connection" shall be understood in a broad sense, for example, may be a fixing connection, a detachable connection, an integral connection, a mechanical connection, an electrical connection, a direct connection, an indirect connection by using an intermediate medium, and communication between interiors of two components. A person of ordinary skill in the art may understand specific meanings of the terms in this application according to specific situations.

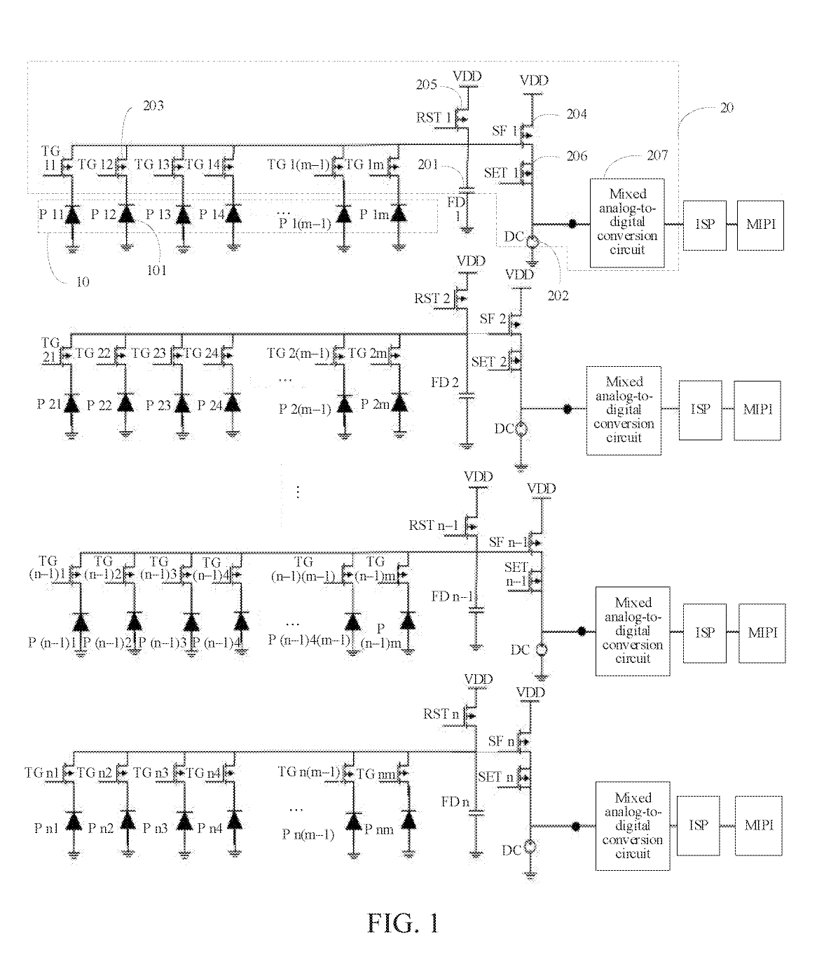

Refer to FIG. 1. An embodiment of this application provides a pixel circuit. As shown in FIG. 1, the pixel circuit includes a photosensitive diode array 10 and at least one voltage detection circuit 20, where

m photosensitive diodes 101 in the photosensitive diode array 10 are electrically connected to one voltage detection circuit 20, and the voltage detection circuit is configured to: detect a digital voltage value corresponding to an analog voltage outputted by a first photosensitive diode in the m photosensitive diodes 101 and a ratio of an analog voltage outputted by m–1 second photosensitive diodes in the m photosensitive diodes 101 to the analog voltage outputted by the first photosensitive diode, and determine a digital voltage value of the m–1 second photosensitive diodes based on the digital voltage value of the first photosensitive diode and the ratio; and

the m photosensitive diodes include at least one row or at least one column of photosensitive diodes 101 in the photosensitive diode array.

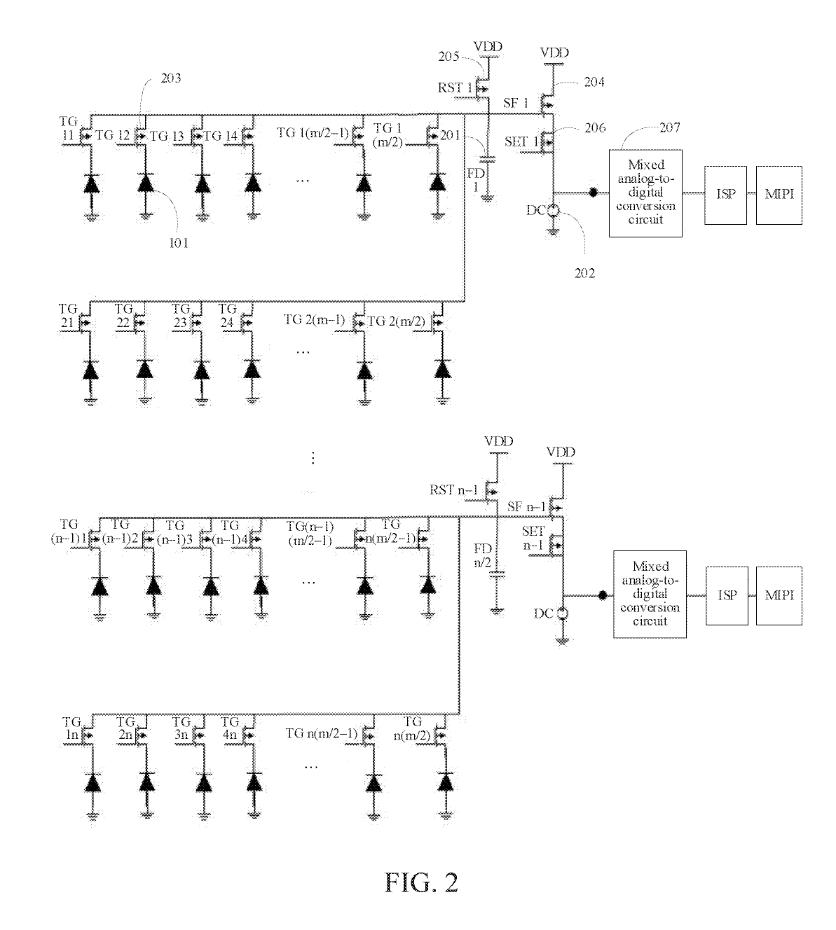

In this embodiment of this application, one voltage detection circuit 20 may be connected to at least one row or at least one column of photosensitive diodes 101. For example, in some embodiments, one voltage detection circuit 20 may be disposed for each row of photosensitive diodes 101, as shown in FIG. 1. Alternatively, one voltage detection circuit 20 may be disposed for every two rows of photosensitive diodes 101, as shown in FIG. 2. When a quantity of voltage detection circuits 20 is at least two, a quantity of photosensitive diodes 101 connected to each voltage detection circuit 20 may be the same or may be different.

It should be noted that, in some embodiments, one ADC and one integration circuit are disposed for each photosensitive diode 101 in each row or column of photosensitive diodes 101 in which the voltage detection circuit 20 is not disposed, and a digital voltage value of each photosensitive diode 101 is obtained through scanning. For details, refer to related technologies, and this is not further limited herein.

It should be understood that, after obtaining digital voltage values of all the photosensitive diodes 101, the digital voltage values may be transferred to an application (AP) processor through mobile industry processor interface (MIPI) encoding after in-system programmability (ISP) processing, and converted into a JPG form for previewing or saving an image.

Optionally, the ratio of the analog voltage outputted by m–1 second photosensitive diodes in the m photosensitive diodes 101 to the analog voltage outputted by the first photosensitive diode may be understood as a ratio of an analog voltage outputted by each second photosensitive diode in the m photosensitive diodes 101 to the analog voltage outputted by the first photosensitive diode.

In this embodiment of this application, the pixel circuit is set to include a photosensitive diode array 10 and at least one voltage detection circuit 20, where the m photosensitive diodes 101 in the photosensitive diode array 10 are electrically connected to one voltage detection circuit 20, the voltage detection circuit is configured to: detect the digital voltage value corresponding to the analog voltage outputted by the first photosensitive diode in the m photosensitive diodes 101 and the ratio of the analog voltage outputted by the m–1 second photosensitive diodes in the m photosensitive diodes 101 to the analog voltage outputted by the first photosensitive diode, and determine the digital voltage value of the m–1 second photosensitive diodes based on the digital voltage value of the first photosensitive diode and the ratio, and the m photosensitive diodes include at least one row or at least one column of photosensitive diodes 101 in the photosensitive diode array. In this way, because the digital voltage value of the m–1 second photosensitive diodes is determined based on the digital voltage value of the first photosensitive diode and the ratio of the analog voltage outputted by the m–1 second photosensitive diodes in the m photosensitive diodes 101 to the analog voltage outputted by the first photosensitive diode, a digital voltage value of the m photosensitive diodes 101 may be obtained by integrating a light signal for only once. Therefore, a time of obtaining the digital voltage value of the photosensitive diodes 101 can be reduced, thereby reducing a time delay in image generation.

Optionally, in some embodiments, the voltage detection circuit includes a floating amplifier 201, a reference direct current power supply 202, a first switch transistor 203, a second switch transistor 204, a reset switch transistor 205, a row selection switch transistor 206, and a mixed analog-to-digital conversion circuit 207.

A quantity of first switch transistors 203 is m, and the m first switch transistors 203 are connected to the m photosensitive diodes 101 in a one-to-one correspondence.

A first end of the floating amplifier 201 is electrically connected to cathodes of the m photosensitive diodes 101 through the m first switch transistors 203, the first end of the floating amplifier 201 is further electrically connected to a high-level end VDD through the reset switch transistor 205, the first end of the floating amplifier 201 is connected to a control end of the second switch transistor 204, a second end of the floating amplifier 201 is connected to the ground, and anodes of the m photosensitive diodes 101 are connected to the ground.

A positive output end of the reference direct current power supply 202 is electrically connected to the high-level end VDD sequentially through the row selection switch transistor 206 and the second switch transistor 204, and the positive output end of the reference direct current power supply 202 is further connected to the mixed analog-to-digital conversion circuit 207.

The mixed analog-to-digital conversion circuit 207 is configured to: detect the digital voltage value corresponding to the analog voltage outputted by the first photosensitive diode in the m photosensitive diodes and the ratio of the analog voltage outputted by m–1 second photosensitive diodes in the m photosensitive diodes to the analog voltage outputted by the first photosensitive diode, and determine the digital voltage value of the m–1 second photosensitive diodes based on the digital voltage value of the first photosensitive diode and the ratio.

In this embodiment of this application, the floating amplifier 201 may be referred to as a capacitor. The first switch transistor 203, the second switch transistor 204, the reset switch transistor 205, and the row selection switch transistor 206 may be a field-effect transistor, or may be another transistor or logic gate circuit that can implement a field-effect transistor function. This is not further limited herein, for example, the first switch transistor 203, the second switch transistor 204, the reset switch transistor 205, and the row selection switch transistor 206 may be a triode in some embodiments.

Optionally, in some implementations, the second switch transistor 204 may be understood as a source follower. During operation, first, the first switch transistor 203 and the reset switch transistor 205 may be controlled to be simultaneously turned on, to empty the floating amplifier 201, and then, the first switch transistor 203 and the reset switch transistor 205 are disconnected to start exposure. An electron-electron hole pair illustrated in a focus region is separated due to an electric field of the photosensitive diode. An electron moves to an n region and an electron hole moves to a p region. When exposure ends, the second switch transistor 204 is activated and turned on to reset the floating amplifier 201 to a high level. After resetting is completed, a level of the floating amplifier 201 is read. After the level of the floating amplifier 201 passes through the second switch transistor 204 and the row selection switch transistor, an analog voltage outputted by one photosensitive diode may be obtained at an output end of the reference direct current power supply. Analog voltages outputted by the m photosensitive diodes may be obtained by sequentially switching and controlling different first switch transistors 203 to be in a turned-on state, and the analog voltage outputted by each photosensitive diode is outputted to the mixed analog-to-digital conversion circuit 207.

It should be noted that, in this embodiment of this application, the analog voltages of the m photosensitive diodes may be inputted to the mixed analog-to-digital conversion circuit 207 in series, that is, the analog voltage of one photosensitive diode is obtained at a same moment, and is inputted to the mixed analog-to-digital conversion circuit 207. In this way, complexity and costs of the circuit can be reduced.

In this embodiment of this application, it is set that a same row or a same column of photosensitive diodes 101 is respectively connected to a same floating amplifier 201, so that the analog voltages of the photosensitive diodes 101 in a same row or a same column may be outputted in series. In this way, circuit cabling difficulty can be reduced, thereby facilitating industrial production.

In some embodiments, the analog voltages of the m photosensitive diodes may be inputted in parallel to the mixed analog-to-digital conversion circuit 207. For example, one floating amplifier 201, one reference direct current power supply 202, one second switch transistor 204, one reset switch transistor 205, and one row selection switch transistor 206 may be disposed for each photosensitive diode.

For another example, one floating amplifier 201, one reference direct current power supply 202, one second switch transistor 204, one reset switch transistor 205, and one row selection switch transistor 206 are disposed for the first photosensitive diode in the m photosensitive diodes, in addition, one floating amplifier 201, one reference direct current power supply 202, one second switch transistor 204, one reset switch transistor 205, and one row selection switch transistor 206 are disposed for all second photosensitive diodes in the m photosensitive diodes, that is, analog voltages of the first photosensitive diode and the second photosensitive diode are inputted to the mixed analog-to-digital conversion circuit 207 in parallel, and the analog voltages of the m–1 second photosensitive diodes are inputted to the mixed analog-to-digital conversion circuit 207 in series. In this case, assuming that the m photosensitive diodes form one row of photosensitive diodes, the second photosensitive diode in each row of photosensitive diodes 101 is electrically connected to the same floating amplifier 201 through the first switch transistor 203, or assuming that the m photosensitive diodes form one column of photosensitive diodes, the second photosensitive diode in each column of photosensitive diodes 101 is electrically connected to the same floating amplifier 201 through the first switch transistor 203.

It should be noted that, each row or column is electrically connected to the floating amplifier through the first switch transistor, so that digital voltage values of all the photosensitive diodes 101 can be read simultaneously, thereby achieving an effect of a global shutter, resolving a jelly effect such as tilting or fluctuation of photographing in a process of scanning row by row, and improving photo and video recording effects.

Optionally, in some embodiments, the photosensitive diode array includes m*N photosensitive diodes, where

N represents a quantity of rows of photosensitive diodes, m represents a quantity of columns of photosensitive diodes, and the m photosensitive diodes form one row of photosensitive diodes; or

m represents a quantity of rows of photosensitive diode, N represents a quantity of columns of photosensitive diode, and the m photosensitive diodes form one column of photosensitive diodes.

In this embodiment of this application, m representing a quantity of columns of photosensitive diodes may be understood that one mixed analog-to-digital conversion circuit 207 is disposed for each row, and the mixed analog-to-digital conversion circuit 207 may read out a digital voltage value of one row of photosensitive diodes. As shown in FIG. 1, the first row of photosensitive diodes may include a PD 11 to a PD 1m, and an n^{th} row of photosensitive diodes may include a PD n1 to a PD nm. Assuming that photosensitive diodes in a first column are the first photosensitive diodes, the first photosensitive diode in the first row of photosensitive diodes may be the PD 11, and the first photosensitive diode in the n^{th} row of photosensitive diodes may be the PD n1. n is a positive integer less than or equal to N. In this embodiment of this application, the first switch transistor 203 in the at least one voltage detection circuit 20 includes a TG 11 to a TG 1m, a TG 21 to a TG 2m, …, a TG (n–1)1 to a TG (n–1)m, and a TG n1 to a TG nm, the second switch transistor 204 includes an SF 1 to an SF n, the reset switch transistor 205 includes an RST 1 to an RST n, the row selection switch transistor 206 includes an SET 1 to an SET n, and the floating amplifier 201 includes an FD 1 to an FD n.

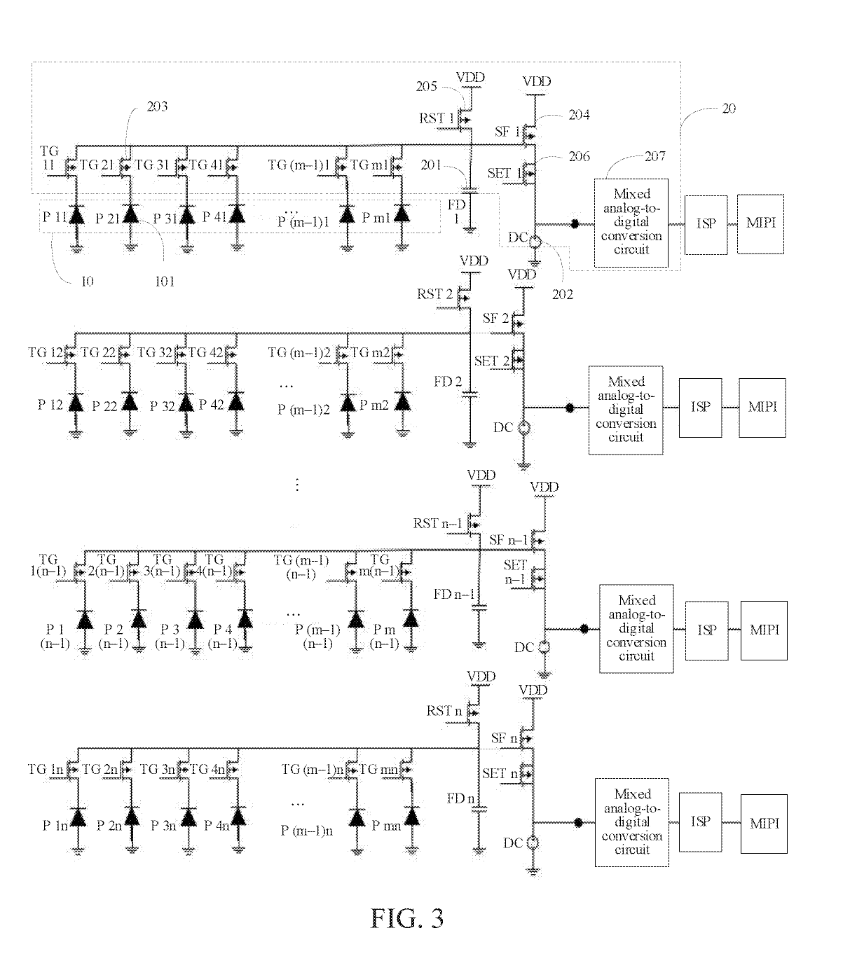

Optionally, m representing a quantity of rows of photosensitive diodes may be understood that one mixed analog-to-digital conversion circuit 207 is disposed for each column, and the mixed analog-to-digital conversion circuit 207 may read out a digital voltage value of one column of photosensitive diodes. As shown in FIG. 3, the first column of photosensitive diodes may include a PD 11 to a PD m1, and the n^{th} column of photosensitive diodes may include a PD 1n to a PD mn. Assuming that photosensitive diodes in the first row are the first photosensitive diodes, the first photosensitive diode in the first column of photosensitive diodes may be the PD 11, and the first photosensitive diode in the n^{th} column of photosensitive diodes may be the PD 1n. n is a positive integer less than or equal to N. In this embodiment of this application, the first switch transistor 203 in the at least one voltage detection circuit 20 includes a TG 11 to a TG m1, a TG 12 to a TG m2, …, a TG 1(n–1) to a TG m(n–1), and a TG 1n to a TG mn, the second switch transistor 204 includes an SF 1 to an SF m, the reset switch transistor 205 includes an RST 1 to an RST m, the row selection switch transistor 206 includes an SET 1 to an SET m, and the floating amplifier 201 includes an SF 1 to an SF m.

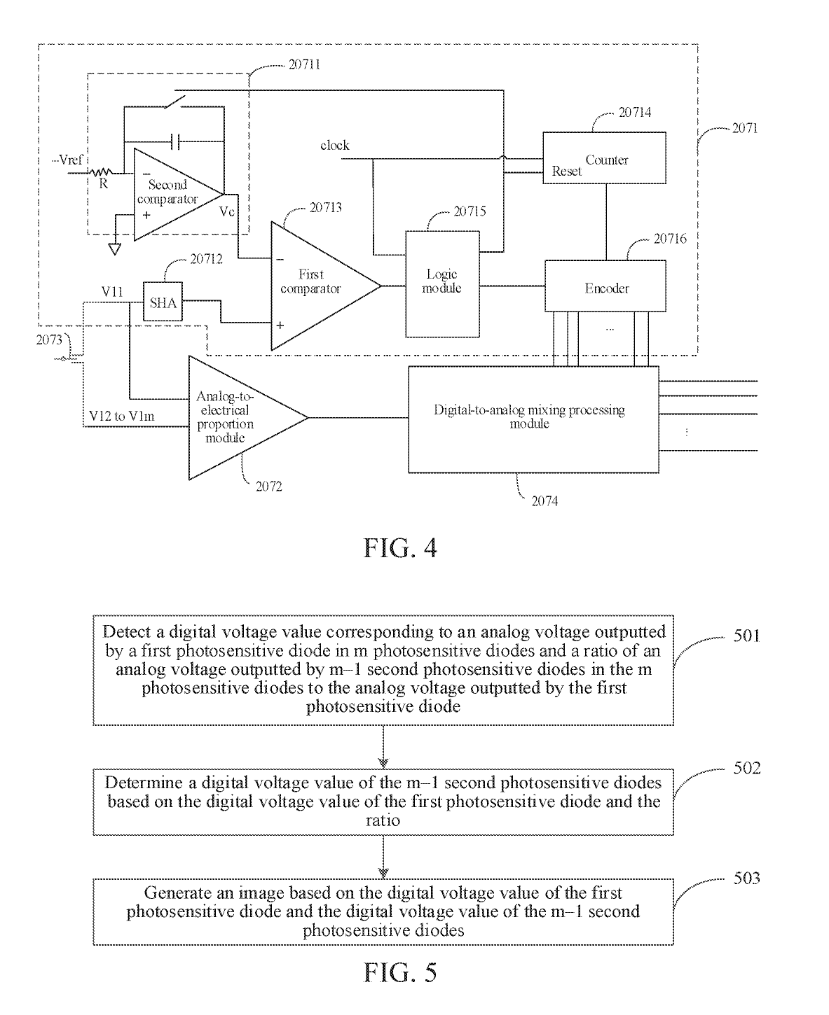

Optionally, refer to FIG. 4 together. In some embodiments, the mixed analog-to-digital conversion circuit 207 includes an integration detection circuit 2071, an analog-to-electrical proportion module 2072, a third switch 2073, and a digital-to-analog mixing processing module 2074, where the integration detection circuit 2071 is connected to the positive output end of the reference direct current power supply 202 through the third switch 2073, the integration detection circuit is electrically connected to a reference level end –Vref and the digital-to-analog mixing processing module 2074 separately, a first input end of the analog-to-electrical proportion module 2072 is electrically connected to a common connection end of the third switch 2073 and the integration detection circuit 2071, a second input end of the analog-to-electrical proportion module 2072 is electrically connected to the positive output end of the reference direct current power supply 202 through the third switch 2073, and an output end of the analog-to-electrical proportion module 2072 is electrically connected to the digital-to-analog mixing processing module 2074.

The third switch 2073 is configured to control the positive output end of the reference direct current power supply 202 to be electrically connected to the first input end of the analog-to-electrical proportion module 2072 or the second input end of the analog-to-electrical proportion module 2072, the integration detection circuit 2071 is configured to detect the digital voltage value corresponding to the analog voltage outputted by the first photosensitive diode in the m photosensitive diodes 101, the analog-to-electrical proportion module 2072 is configured to detect the ratio of the analog voltage outputted by m–1 second photosensitive diodes in the m photosensitive diodes 101 to the analog voltage outputted by the first photosensitive diode, and the digital-to-analog mixing processing module is configured to determine the digital voltage value of the m–1 second photosensitive diodes based on the digital voltage value of the first photosensitive diode and the ratio.

In this embodiment of this application, the third switch 2073 may be a single-pole double-throw switch. When controlling the first input end of the analog-to-electrical proportion module 2072 to be in a turned-on connection with the positive output end of the reference direct current power supply 202, the third switch 2073 may read the analog voltage of the first photosensitive diode, and output the analog voltage to the analog-to-electrical proportion module 2072 and the integration detection circuit 2071, so that the integration detection circuit detects the digital voltage value corresponding to the analog voltage of the first photosensitive diode.

When controlling the second input end of the analog-to-electrical proportion module 2072 to be in a turned-on connection with the positive output end of the reference direct current power supply 202, the third switch 2073 may sequentially read the analog voltages of the m–1 second photosensitive diodes, and output the analog voltages to the second input end of the analog-to-electrical proportion module 2072 in series. The analog-to-electrical proportion module 2072 may output a proportion vector. The proportion vector is used to represent a ratio of each second photosensitive diode to the first photosensitive diode.

It should be noted that, when the analog voltages of the m–1 second photosensitive diodes are inputted in parallel to the analog-to-electrical proportion module 2072, the analog-to-electrical proportion module 2072 needs to support a parallel input mode, that is, needs to include a plurality of second input ends. When the analog-to-electrical proportion module 2072 includes the plurality of second input ends, the analog voltages of the m–1 second photosensitive diodes may be divided in group and inputted in parallel.

Optionally, in some embodiments, the integration detection circuit 2071 includes an integration circuit 20711, a sample-and-hold amplifier (SHA) 20712, a first comparator 20713, a counter 20714, a logic module 20715, and an encoder 20716.

An input end of the integration circuit 20711 is electrically connected to the reference level end –Vref, and an output end of the integration circuit is connected to an input end of the first comparator 20713.

An input end of the sample-and-hold amplifier 20712 is electrically connected to the positive output end of the reference direct current power supply 202 through the third switch 2073, the input end of the sample-and-hold amplifier 20712 is electrically connected to the first input end of the analog-to-electrical proportion module 2072, and an output end of the sample-and-hold amplifier 20712 is connected to the other input end of the first comparator 20713.

An output end of the first comparator 20713 is electrically connected to the logic module 20715.

The logic module 20715 is electrically connected to a control end of the integration circuit 20711, and the logic module 20715 is electrically connected to the counter 20714 and the encoder 20716 separately.

The encoder 20716 is electrically connected to the counter 20714 and the digital-to-analog mixing processing module 2074 separately.

In this embodiment of this application, the foregoing integration circuit may include a second comparator, a resistor, a capacitor, and a fourth switch transistor. A first input end of the second comparator is electrically connected to the reference level end –Vref through the resistor, the first input end of the second comparator is electrically connected to an output end of the second comparator through the capacitor, a second input end of the second comparator is connected to the ground, the fourth switch transistor is connected in parallel to two ends of the capacitor, and the fourth switch transistor is electrically connected to the logic module 20715.

It should be noted that, under control of the logic module 20715, the integration circuit 20711 turns on and turns off the fourth switch transistor based on a fixed frequency, so that –Vref is increased in a fixed step and Vc is outputted. Vc is connected to an input end of a comparison circuit. An example in which the m photosensitive diodes 101 are the photosensitive diodes 101 in the first row is used for description. The analog voltages outputted by the photosensitive diodes 101 in the first row are V11 to V1m. V11 is inputted to the first comparator 20713 and the analog-to-electrical proportion module 2072. V12 to V1m also need to be inputted to the analog-to-electrical proportion module 2072.

The second comparator determines whether Vc reaches V11. When Vc reaches V11, the first comparator 20713 outputs a signal to the logic module 20715, and controls the encoder 20716 to output a corresponding digital value (that is, a digital voltage value) of V11, and the digital value is transmitted to the digital-to-analog mixing processing module 2074.

V12 to V1m are all inputted to the analog-to-electrical proportion module 2072. The analog-to-electrical proportion module 2072 uses V11 as a reference voltage, and calculates proportion vectors of V12 to V1m relative to V11 separately. Assuming that V11 is 10V and V12 is 15V, the proportion vector of V12 is 1.5. Similarly, proportion vectors of other photosensitive diodes 101 may also be calculated. The proportion vector also needs to be inputted to the digital-to-analog mixing processing module 2074.

The digital-to-analog mixing processing module 2074 may perform calculation based on the proportion vector and the digital value V11, to obtain all digital values of V12 to V1m. For example, if a numerical value of V11 is 500 LSB, and a proportion vector of V12 is 1.5, a numerical value of V12 is 750 LSB.

Optionally, an embodiment of this application further provides an electronic device, and the electronic device includes a pixel circuit. For a structure of the pixel circuit, refer to the foregoing embodiment. Details are not described herein again. Because the electronic device provided in this embodiment of this application includes the pixel circuit in the foregoing embodiment, the electronic device provided in this embodiment of this application has all beneficial effects of the pixel circuit in the foregoing embodiment.

Optionally, refer to FIG. 5. An embodiment of this application further provides an image obtaining method, applied to the foregoing electronic device. As shown in FIG. 5, the method includes the following steps.

Step 501: Detect a digital voltage value corresponding to an analog voltage outputted by a first photosensitive diode in m photosensitive diodes and a ratio of an analog voltage outputted by m–1 second photosensitive diodes in the m photosensitive diodes to the analog voltage outputted by the first photosensitive diode.

Step 502: Determine a digital voltage value of the m–1 second photosensitive diodes based on the digital voltage value of the first photosensitive diode and the ratio.

Step 503: Generate an image based on the digital voltage value of the first photosensitive diode and the digital voltage value of the m–1 second photosensitive diodes.

The m photosensitive diodes include at least one row or at least one column of photosensitive diodes in a photosensitive diode array.

In this embodiment of this application, the digital voltage value of the m–1 second photosensitive diodes is determined based on the digital voltage value of the first photosensitive diode and the ratio of the analog voltage outputted by the m–1 second photosensitive diodes in the m photosensitive diodes to the analog voltage outputted by the first photosensitive diode, so that a digital voltage value of the m photosensitive diodes may be obtained by integrating a light signal for only once. Therefore, a time of obtaining the digital voltage value of the photosensitive diode can be reduced, thereby reducing a time delay in image generation.

Optionally, the detecting a ratio of an analog voltage outputted by m–1 second photosensitive diodes in the m photosensitive diodes to the analog voltage outputted by the first photosensitive diode includes:

detecting an analog output voltage of the first photosensitive diode and an analog output voltage of the m–1 second photosensitive diodes in the m photosensitive diode; and

separately inputting the analog voltage outputted by the first photosensitive diode and the analog voltages outputted by the m–1 second photosensitive diodes in the m photosensitive diodes to an analog-to-electrical proportion module, to obtain the ratio of the analog voltage outputted by the m–1 second photosensitive diodes in the m photosensitive diodes to the analog voltage outputted by the first photosensitive diode.

Optionally, the separately inputting the analog voltage outputted by the first photosensitive diode and the analog voltages outputted by the m–1 second photosensitive diodes in the m photosensitive diodes to an analog-to-electrical proportion module includes:

inputting, at a first moment, the analog voltage outputted by the first photosensitive diode to a first input end of the analog-to-electrical proportion module; and

separately inputting, at different moments, the analog voltages outputted by the m–1 second photosensitive diodes to a second input end of an analog-to-electrical proportion module, where

a moment at which the analog voltage outputted by the second photosensitive diode is inputted to the second input end of the analog-to-electrical proportion module is after the first moment.

In the descriptions of this specification, the descriptions of the reference terms such as "an embodiment", "some embodiments", "exemplary embodiments", "example", "specific example", or "some examples" means that the specific features, structures, materials or characteristics described with reference to the embodiment or example are included in at least one embodiment or example of this application. In this specification, schematic descriptions of the foregoing terms are not necessarily directed at a same embodiment or example. In addition, the described specific feature, structure, material, or characteristic may be combined in a proper manner in any one or more embodiments or examples.

Although embodiments of this application have been shown and described, a person skilled in the art can understand that changes, alternatives, and modifications can be made in embodiments without departing from the principle and the purpose of this application, and the scope of this application is as defined by the claims and their equivalents.

What is claimed is:

1. A pixel circuit, comprising a photosensitive diode array and at least one voltage detection circuit, wherein
m photosensitive diodes in the photosensitive diode array are electrically connected to one voltage detection circuit, and the voltage detection circuit is configured to: detect a digital voltage value corresponding to an analog voltage outputted by a first photosensitive diode in the m photosensitive diodes and a ratio of an analog voltage outputted by m–1 second photosensitive diodes in the m photosensitive diodes to the analog voltage outputted by the first photosensitive diode, and determine a digital voltage value of the m–1 second photosensitive diodes based on the digital voltage value of the first photosensitive diode and the ratio; and
the m photosensitive diodes comprise at least one row or at least one column of photosensitive diodes in the photosensitive diode array.

2. The pixel circuit according to claim 1, wherein the voltage detection circuit comprises a floating amplifier, a reference direct current power supply, a first switch transistor, a second switch transistor, a reset switch transistor, a row selection switch transistor, and a mixed analog-to-digital conversion circuit, wherein
a quantity of first switch transistors is m, and the m first switch transistors and the m photosensitive diodes are connected in a one-to-one correspondence;
a first end of the floating amplifier is electrically connected to cathodes of the m photosensitive diodes through the m first switch transistors, the first end of the floating amplifier is further electrically connected to a high-level end through the reset switch transistor, the first end of the floating amplifier is connected to a control end of the second switch transistor, a second end of the floating amplifier is connected to the ground, and anodes of the m photosensitive diodes are connected to the ground;
a positive output end of the reference direct current power supply is electrically connected to the high-level end sequentially through the row selection switch transistor and the second switch transistor, and the positive output end of the reference direct current power supply is further connected to the mixed analog-to-digital conversion circuit; and
the mixed analog-to-digital conversion circuit is configured to: detect the digital voltage value corresponding to the analog voltage outputted by the first photosensitive diode in the m photosensitive diodes and the ratio of the analog voltage outputted by m–1 second photosensitive diodes in the m photosensitive diodes to the analog voltage outputted by the first photosensitive diode, and determine the digital voltage value of the m–1 second photosensitive diodes based on the digital voltage value of the first photosensitive diode and the ratio.

3. The pixel circuit according to claim 2, wherein each row of photosensitive diodes is electrically connected to a same floating amplifier through the first switch transistor, or each column of photosensitive diodes is electrically connected to a same floating amplifier through the first switch transistor.

4. The pixel circuit according to claim 3, wherein the photosensitive diode array comprises m*N photosensitive diodes, wherein
N represents a quantity of rows of photosensitive diodes, m represents a quantity of columns of photosensitive diodes, and the m photosensitive diodes form one row of photosensitive diodes; or
m represents a quantity of rows of photosensitive diode, N represents a quantity of columns of photosensitive diode, and the m photosensitive diodes form one column of photosensitive diodes.

5. The pixel circuit according to claim 2, wherein the mixed analog-to-digital conversion circuit comprises an integration detection circuit, an analog-to-electrical proportion module, a third switch, and a digital-to-analog mixing processing module, wherein the integration detection circuit is connected to the positive output end of the reference direct current power supply through the third switch, the integration detection circuit is electrically connected to a reference level end and the digital-to-analog mixing processing module separately, a first input end of the analog-to-electrical proportion module is electrically connected to a common connection end of the third switch and the integration detection circuit, a second input end of the analog-to-electrical proportion module is electrically connected to the positive output end of the reference direct current power supply through the third switch, and an output end of the analog-to-electrical proportion module is electrically connected to the digital-to-analog mixing processing module; and
the third switch is configured to control the positive output end of the reference direct current power supply to be electrically connected to the first input end of the analog-to-electrical proportion module or the second input end of the analog-to-electrical proportion module, the integration detection circuit is configured to detect the digital voltage value corresponding to the analog voltage outputted by the first photosensitive diode in the m photosensitive diodes, the analog-to-electrical proportion module is configured to detect the ratio of the analog voltage outputted by m–1 second photosensitive diodes in the m photosensitive diodes to the analog voltage outputted by the first photosensitive diode, and the digital-to-analog mixing processing module is configured to determine the digital voltage value of the m–1 second photosensitive diodes based on the digital voltage value of the first photosensitive diode and the ratio.

6. The pixel circuit according to claim 5, wherein the integration detection circuit comprises an integration circuit, a sample-and-hold amplifier, a first comparator, a counter, a logic module, and an encoder;
an input end of the integration circuit is electrically connected to the reference level end, and an output end of the integration circuit is connected to an input end of the first comparator;
an input end of the sample-and-hold amplifier is electrically connected to the positive output end of the reference direct current power supply through the third switch, the input end of the sample-and-hold amplifier is electrically connected to the first input end of the analog-to-electrical proportion module, and an output end of the sample-and-hold amplifier is connected to the other input end of the first comparator;
an output end of the first comparator is electrically connected to the logic module;
the logic module is electrically connected to a control end of the integration circuit, and the logic module is electrically connected to the counter and the encoder separately; and
the encoder is electrically connected to the counter and the digital-to-analog mixing processing module separately.

7. An electronic device, comprising a pixel circuit; wherein the pixel circuit comprises a photosensitive diode array and at least one voltage detection circuit, wherein
m photosensitive diodes in the photosensitive diode array are electrically connected to one voltage detection circuit, and the voltage detection circuit is configured to: detect a digital voltage value corresponding to an analog voltage outputted by a first photosensitive diode in the m photosensitive diodes and a ratio of an analog voltage outputted by m–1 second photosensitive diodes in the m photosensitive diodes to the analog voltage outputted by the first photosensitive diode, and determine a digital voltage value of the m–1 second photosensitive diodes based on the digital voltage value of the first photosensitive diode and the ratio; and
the m photosensitive diodes comprise at least one row or at least one column of photosensitive diodes in the photosensitive diode array.

8. The electronic device according to claim 7, wherein the voltage detection circuit comprises a floating amplifier, a reference direct current power supply, a first switch transistor, a second switch transistor, a reset switch transistor, a row selection switch transistor, and a mixed analog-to-digital conversion circuit, wherein
a quantity of first switch transistors is m, and the m first switch transistors and the m photosensitive diodes are connected in a one-to-one correspondence;
a first end of the floating amplifier is electrically connected to cathodes of the m photosensitive diodes through the m first switch transistors, the first end of the floating amplifier is further electrically connected to a high-level end through the reset switch transistor, the first end of the floating amplifier is connected to a control end of the second switch transistor, a second end of the floating amplifier is connected to the ground, and anodes of the m photosensitive diodes are connected to the ground;
a positive output end of the reference direct current power supply is electrically connected to the high-level end sequentially through the row selection switch transistor and the second switch transistor, and the positive output end of the reference direct current power supply is further connected to the mixed analog-to-digital conversion circuit; and
the mixed analog-to-digital conversion circuit is configured to: detect the digital voltage value corresponding to the analog voltage outputted by the first photosensitive diode in the m photosensitive diodes and the ratio of the analog voltage outputted by m–1 second photosensitive diodes in the m photosensitive diodes to the analog voltage outputted by the first photosensitive diode, and determine the digital voltage value of the m–1 second photosensitive diodes based on the digital voltage value of the first photosensitive diode and the ratio.

9. The electronic device according to claim 8, wherein each row of photosensitive diodes is electrically connected to a same floating amplifier through the first switch transistor, or each column of photosensitive diodes is electrically connected to a same floating amplifier through the first switch transistor.

10. The electronic device according to claim 9, wherein the photosensitive diode array comprises m*N photosensitive diodes, wherein
N represents a quantity of rows of photosensitive diodes, m represents a quantity of columns of photosensitive diodes, and the m photosensitive diodes form one row of photosensitive diodes; or
m represents a quantity of rows of photosensitive diode, N represents a quantity of columns of photosensitive diode, and the m photosensitive diodes form one column of photosensitive diodes.

11. The electronic device according to claim 8, wherein the mixed analog-to-digital conversion circuit comprises an integration detection circuit, an analog-to-electrical proportion module, a third switch, and a digital-to-analog mixing processing module, wherein the integration detection circuit is connected to the positive output end of the reference direct current power supply through the third switch, the integration detection circuit is electrically connected to a reference level end and the digital-to-analog mixing processing module separately, a first input end of the analog-to-electrical proportion module is electrically connected to a common connection end of the third switch and the integration detection circuit, a second input end of the analog-to-electrical proportion module is electrically connected to the positive output end of the reference direct current power supply through the third switch, and an output end of the analog-to-electrical proportion module is electrically connected to the digital-to-analog mixing processing module; and
the third switch is configured to control the positive output end of the reference direct current power supply to be electrically connected to the first input end of the analog-to-electrical proportion module or the second input end of the analog-to-electrical proportion module, the integration detection circuit is configured to detect the digital voltage value corresponding to the analog voltage outputted by the first photosensitive diode in the m photosensitive diodes, the analog-to-electrical proportion module is configured to detect the ratio of the analog voltage outputted by m–1 second photosensitive diodes in the m photosensitive diodes to the analog voltage outputted by the first photosensitive diode, and the digital-to-analog mixing processing module is configured to determine the digital voltage value of the m–1 second photosensitive diodes based on the digital voltage value of the first photosensitive diode and the ratio.

12. The electronic device according to claim 11, wherein the integration detection circuit comprises an integration circuit, a sample-and-hold amplifier, a first comparator, a counter, a logic module, and an encoder;
an input end of the integration circuit is electrically connected to the reference level end, and an output end of the integration circuit is connected to an input end of the first comparator;
an input end of the sample-and-hold amplifier is electrically connected to the positive output end of the reference direct current power supply through the third switch, the input end of the sample-and-hold amplifier is electrically connected to the first input end of the analog-to-electrical proportion module, and an output end of the sample-and-hold amplifier is connected to the other input end of the first comparator;
an output end of the first comparator is electrically connected to the logic module;
the logic module is electrically connected to a control end of the integration circuit, and the logic module is electrically connected to the counter and the encoder separately; and
the encoder is electrically connected to the counter and the digital-to-analog mixing processing module separately.

13. An image obtaining method, applied to an electronic device comprising a pixel circuit; wherein the pixel circuit comprises a photosensitive diode array and at least one voltage detection circuit, wherein
m photosensitive diodes in the photosensitive diode array are electrically connected to one voltage detection circuit, and the voltage detection circuit is configured to: detect a digital voltage value corresponding to an analog voltage outputted by a first photosensitive diode in the m photosensitive diodes and a ratio of an analog voltage outputted by m–1 second photosensitive diodes in the m photosensitive diodes to the analog voltage outputted by the first photosensitive diode, and determine a digital voltage value of the m–1 second photosensitive diodes based on the digital voltage value of the first photosensitive diode and the ratio; and
the m photosensitive diodes comprise at least one row or at least one column of photosensitive diodes in the photosensitive diode array; wherein the image obtaining method comprises:
detecting a digital voltage value corresponding to an analog voltage outputted by a first photosensitive diode in m photosensitive diodes and a ratio of an analog voltage outputted by m–1 second photosensitive diodes in the m photosensitive diodes to the analog voltage outputted by the first photosensitive diode;
determining the digital voltage value of the m–1 second photosensitive diodes based on the digital voltage value of the first photosensitive diode and the ratio; and
generating an image based on the digital voltage value of the first photosensitive diode and the digital voltage value of the m–1 second photosensitive diodes, wherein
the m photosensitive diodes comprise at least one row or at least one column of photosensitive diodes in a photosensitive diode array.

14. The method according to claim 13, wherein the detecting a ratio of an analog voltage outputted by m–1 second photosensitive diodes in the m photosensitive diodes to the analog voltage outputted by the first photosensitive diode comprises:
detecting an analog output voltage of the first photosensitive diode and an analog output voltage of the m–1 second photosensitive diodes in the m photosensitive diode; and
separately inputting the analog voltage outputted by the first photosensitive diode and the analog voltages outputted by the m–1 second photosensitive diodes in the m photosensitive diodes to an analog-to-electrical proportion module, to obtain the ratio of the analog voltage outputted by the m–1 second photosensitive diodes in the m photosensitive diodes to the analog voltage outputted by the first photosensitive diode.

15. The method according to claim 14, wherein the separately inputting the analog voltage outputted by the first photosensitive diode and the analog voltages outputted by the m–1 second photosensitive diodes in the m photosensitive diodes to an analog-to-electrical proportion module comprises:
inputting, at a first moment, the analog voltage outputted by the first photosensitive diode to a first input end of the analog-to-electrical proportion module; and
separately inputting, at different moments, the analog voltages outputted by the m–1 second photosensitive diodes to a second input end of an analog-to-electrical proportion module, wherein
a moment at which the analog voltage outputted by the second photosensitive diode is inputted to the second input end of the analog-to-electrical proportion module is after the first moment.
